(19) United States
(12) Patent Application Publication
(10) Pub. No.: US 2025/0031585 A1
(43) Pub. Date: Jan. 23, 2025

(54) RESISTIVE RANDOM ACCESS MEMORY AND METHOD OF MANUFACTURING THE SAME

(71) Applicant: United Microelectronics Corp., Hsinchu (TW)

(72) Inventors: Zhaoyao Zhan, Singapore (SG); Jian Shi, Singapore (SG); Xiaohong Jiang, Singapore (SG); Ching-Hwa Tey, Singapore (SG)

(73) Assignee: United Microelectronics Corp., Hsinchu (TW)

(21) Appl. No.: 18/447,317

(22) Filed: Aug. 10, 2023

(30) Foreign Application Priority Data
Jul. 18, 2023 (TW) 112126630

(51) Int. Cl. H10N 70/00; H10B 63/00

(52) U.S. Cl. CPC H10N 70/021; H10B 63/30; H10N 70/041; H10N 70/063; H10N 70/066; H10N 70/841; G11C 13/0059

(57) ABSTRACT

A resistive random access memory includes a first electrode, a second electrode, a dielectric layer, a protection layer, and at least one switching layer. The dielectric layer is formed on the first electrode. The dielectric layer has an opening exposing a portion of the first electrode. The protection layer is disposed on sidewalls of the opening. The switching layer is disposed on the exposed portion of the first electrode and exposes a portion of sidewalls of the protection layer. The second electrode is at least one conductive layer and is disposed on the switching layer in the opening.

### CROSS-REFERENCE TO RELATED APPLICATION

This application claims the priority benefit of Taiwan application serial no. 112126630, filed on Jul. 18, 2023. The entirety of the above-mentioned patent application is hereby incorporated by reference herein and made a part of this specification.

### BACKGROUND

### Technical Field

The disclosure relates to a resistive random access memory (RRAM) and a method of manufacturing the same.

### Description of Related Art

Many modern electronic devices have memory elements. The memory elements include a volatile memory or a non-volatile memory. Since the volatile memory loses stored data thereof when the power goes out, the non-volatile memory that may retain the stored data even when power is not supplied has become the focus of development. A resistive random access memory is highly anticipated for potential thereof in the next generation of non-volatile memory technology due to superior characteristics thereof over current memory elements.

Generally, the resistive random access memory includes an upper electrode, a lower electrode, and a variable resistance layer disposed between the upper electrode and the lower electrode. In existing manufacturing processes for the resistive random access memory, several photolithography and etching steps are used to define a pattern of a memory unit. However, a process of etching a metal layer for a long time and with high power will cause the plasma to damage a dielectric layer in the memory unit and generate arcing defects. In addition, due to the long etching time, an outline of the memory unit is easily tilted, resulting in low unit area efficiency.

Another existing manufacturing process is to use a single damascene process. An opening is formed first, and a switching layer and a metal electrode are filled in the opening to prevent damage caused by the plasma. However, an excessively large switching layer/metal region will aggravate a forming/read/write current.

### SUMMARY

The disclosure provides a resistive random access memory, which has no plasma damage and may reduce a forming/read/write current, and may further improve performance and reliability of the resistive random access memory.

The disclosure further provides a method of manufacturing the resistive random access memory, which may solve an issue of plasma damage caused by an existing manufacturing process and reduce the forming/read/write current.

A resistive random access memory in the disclosure includes a first electrode, a dielectric layer, a protection layer, at least one switching layer, and at least one conductive layer. The dielectric layer is formed on the first electrode. The dielectric layer has an opening exposing a portion of the first electrode. The protection layer is disposed on a sidewall of the opening. The switching layer is disposed on the exposed portion of the first electrode and exposes a portion of a sidewall of the protection layer. The conductive layer is disposed on the switching layer in the opening. The conductive layer is a second electrode.

In an embodiment of the disclosure, the at least one switching layer includes an extension portion extending on the sidewall of the protection layer.

In an embodiment of the disclosure, the at least one switching layer is a single-layer structure or a multi-layer structure.

In an embodiment of the disclosure, the at least one conductive layer is a single-layer structure or a multi-layer structure.

In an embodiment of the disclosure, the resistive random access memory further includes a stop layer located on a surface of the dielectric layer.

In an embodiment of the disclosure, the conductive layer is in direct contact with the exposed portion of the sidewall of the protection layer.

A method of manufacturing a resistive random access memory in the disclosure includes the following. A first electrode is formed. A dielectric layer is formed on the first electrode. An opening exposing a portion of the first electrode is formed in the dielectric layer. A protection layer is formed on a sidewall of the opening. At least one switching layer is formed on the exposed portion of the first electrode, and a portion of a sidewall of the protection layer is exposed. Then, at least one conductive layer is formed on the switching layer in the opening. The at least one conductive layer is a second electrode.

In another embodiment of the disclosure, a method of forming the protection layer includes the following. A protection material is deposited on the dielectric layer and the sidewall and a bottom of the opening. The protection material is anisotropically etched until the first electrode is exposed.

In another embodiment of the disclosure, a method of forming the at least one switching layer includes the following. At least one switching material is conformally deposited on the sidewall of the protection layer and a bottom of the opening. A portion of the switching material on the sidewall of the protection layer is removed.

In another embodiment of the disclosure, a method of forming the at least one conductive layer includes the following. At least one conductive material is deposited to fill the opening. A planarization process is performed to remove the conductive material other than the opening.

In another embodiment of the disclosure, the planarization process is a chemical mechanical polishing (CMP) process.

In another embodiment of the disclosure, a method of forming the opening in the dielectric layer includes the following. A stop layer is first formed on a surface of the dielectric layer. The stop layer has a hole exposing a portion of the surface of the dielectric layer. Then, the dielectric layer is etched using the stop layer as an etching mask.

In another embodiment of the disclosure, a method of forming the at least one conductive layer includes the following. At least one conductive material is deposited to fill the opening. The stop layer is used as a polishing stop layer, and a chemical mechanical polishing process is performed to remove the conductive material other than the opening.

In order for the aforementioned features of the disclosure to be more comprehensible, embodiments accompanied with drawings are described in detail below.

### BRIEF DESCRIPTION OF THE DRAWINGS

FIG. 1 is a schematic cross-sectional view of a resistive random access memory according to the first embodiment of the disclosure.

FIG. 2 is a schematic cross-sectional view of a resistive random access memory according to the second embodiment of the disclosure.

FIG. 3 is a schematic cross-sectional view of a resistive random access memory according to the third embodiment of the disclosure.

FIGS. 4A to 4J are schematic cross-sectional views of a manufacturing process of a resistive random access memory according to the fourth embodiment of the disclosure.

### DETAILED DESCRIPTION OF DISCLOSED EMBODIMENTS

The disclosure is applied to a resistive random access memory, which may use a protection layer to improve performance and reliability of the resistive random access memory, and may reduce a forming/read/write current by reducing an active region.

Hereinafter, some embodiments are described to illustrate the disclosure, but the disclosure is not limited to the embodiments. Possible combinations are also allowed between the described embodiments.

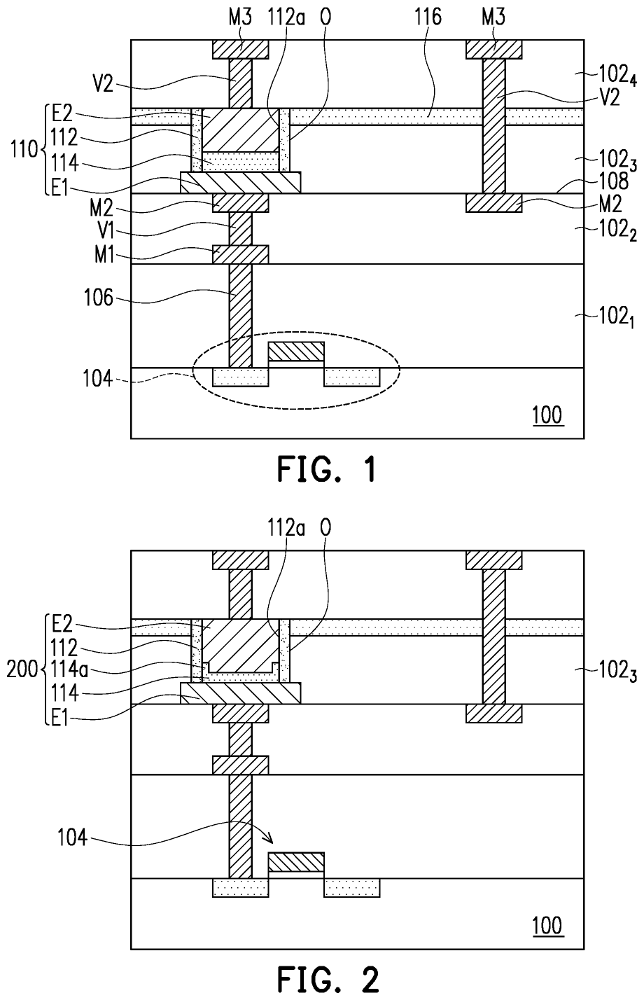

FIG. 1 is a schematic cross-sectional view of a resistive random access memory according to the first embodiment of the disclosure.

Referring to FIG. 1, the resistive random access memory in the first embodiment may be formed in a semiconductor device, and connected to a transistor 104 on a substrate 100 through interconnection. For example, on the substrate 100, the interconnection formed by several dielectric layers 102₁ and 102₂, interconnection metal layers M1 and M2, a contact 106, and a via V1 may electrically connect the transistor 104 to a first electrode E1 of the resistive random access memory. On the substrate 100, the interconnection formed by several dielectric layers 102₃ and 102₄, an interconnection metal layer M3, and a via V2 may externally connect a second electrode E2 of the resistive random access memory. However, the disclosure is not limited thereto. A design of the interconnection, a structure of the transistor 104, etc. above may be adjusted according to requirements. The dielectric layer 102₁ is generally an inner layer dielectric layer, and the dielectric layers 102₂, 102₃, and 102₄ are generally interlayer dielectric layers (ILD).

In FIG. 1, the resistive random access memory includes the first electrode E1, the dielectric layer 102₃, a protection layer 112, a switching layer 114 of a single-layer structure, and a conductive layer of a single-layer structure (i.e., the second electrode E2). The dielectric layer 102₃ is formed on the first electrode E1 and has an opening O exposing a portion of the first electrode E1. The protection layer 112 is disposed on sidewalls of the opening O, and has effects of preventing water vapor, outgas, solvents, etc. from affecting an internal structure thereof, thereby improving the performance and reliability of the resistive random access memory. The switching layer 114 is disposed on the exposed portion of the first electrode E1, and exposes a portion of a sidewall 112a of the protection layer 112, so the active region is within the opening O without reducing an area of the second electrode E2, and thus the forming/read/write current may be reduced. That is to say, the conductive layer (i.e., the second electrode E2) is in direct contact with the exposed portion of the sidewall 112a of the protection layer 112.

Continuing to refer to FIG. 1, the conductive layer (i.e., the second electrode E2) is disposed on the switching layer 114 in the opening O. A stack structure formed by the first electrode E1, the switching layer 114, and the second electrode E2 is a basic structure of a resistive memory unit. The first electrode E1 is in direct contact with the interconnected metal layer M2 below, and a material thereof may be titanium, tantalum, titanium nitride, tantalum nitride, aluminum titanium nitride, titanium tungsten, platinum, iridium, tungsten, ruthenium, graphite, or a combination thereof. A material of the switching layer 114 may be metal oxide or non-metal oxide, such as silicon oxide, germanium oxide, aluminum oxide, tantalum oxide, hafnium oxide, zirconium oxide, zirconium hafnium oxide, aluminum hafnium oxide, hafnium oxynitride, silicon hafnium oxide, strontium hafnium oxide, yttrium hafnium oxide, or a combination thereof. Although the switching layer 114 between the first electrode E1 and the second electrode E2 is shown as the single-layer structure in FIG. 1, the disclosure is not limited thereto. A material of the second electrode E2 nay be the same as or different from the material of the first electrode E1, such as titanium, tantalum, titanium nitride, tantalum nitride, aluminum titanium nitride, titanium tungsten, platinum, iridium, tungsten, ruthenium, graphite, or a combination thereof. In an embodiment, the resistive random access memory may further include a stop layer 116 on a surface of the dielectric layer 102₃. The stop layer 116 may be used as an etch stop layer or a grinding stop layer, which is helpful to a manufacturing process of the resistive random access memory, which will be described in detail below. A material of the stop layer 116 is, for example, silicon nitride or other suitable materials.

FIG. 2 is a schematic cross-sectional view of a resistive random access memory according to the second embodiment of the disclosure. The same or similar parts and components are represented by the same reference numerals as those of the first embodiment, and the relevant content of the same or similar parts and components may also refer to the content of the first embodiment. Therefore, the same details will not be repeated in the following.

Referring to FIG. 2, a resistive random access memory 200 in the second embodiment is the same as that in the first embodiment, including the first electrode E1, the dielectric layer 102₃, the protection layer 112, the switching layer 114, and the second electrode E2, but the switching layer 114 further has an extension portion 114a extending on the sidewall 112a of the protection layer 112. The extension portion 114a is a portion reserved in a process of manufacturing the switching layer 114. For example, the switching layer 114 may be conformally formed on the surface of the first electrode E1 and the entire sidewall 112a of the protection layer 112 inside the opening O through a deposition process. Then, the opening O is filled with a material such as photoresist, and a recess process is performed on it to reserve a portion of the photoresist at a top position of the extension portion 114a. After that, the remaining photoresist is used as a mask to etch and remove the exposed switching layer 114. Therefore, an area of the extension portion 114a covering the sidewall 112a may vary due to the manufacturing process, but it does not cover the entire sidewall 112a to ensure that the active region is within the opening O.

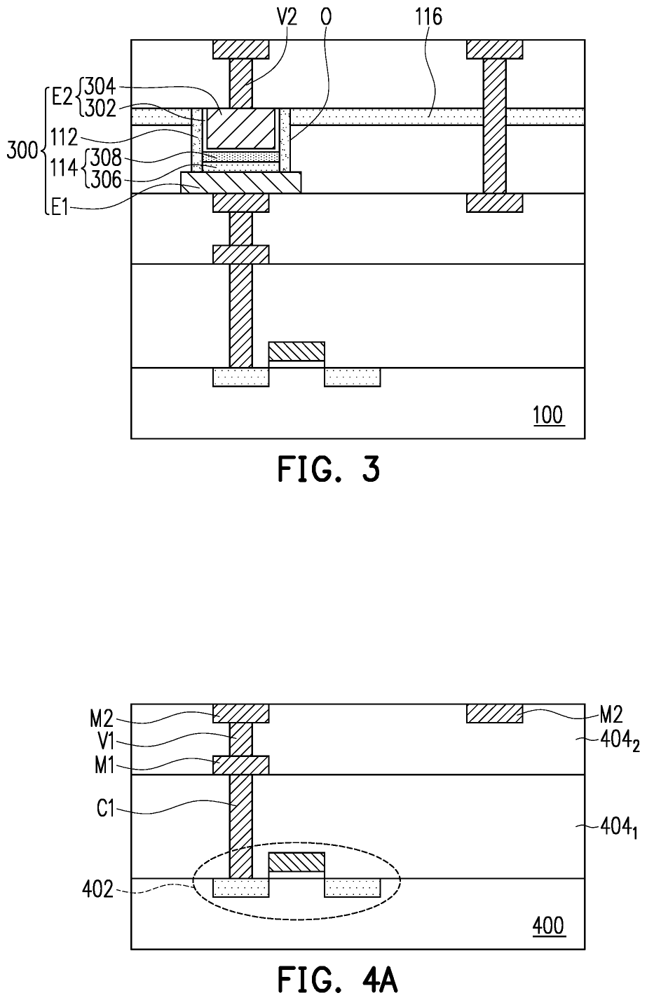

FIG. 3 is a schematic cross-sectional view of a resistive random access memory according to the third embodiment of the disclosure. The same or similar parts and components are represented by the same reference numerals as those of the first embodiment, and the relevant content of the same or similar parts and components may also refer to the content of the first embodiment. Therefore, the same details will not be repeated in the following.

Referring to FIG. 3, a difference between a resistive random access memory 300 in the third embodiment and that in the first embodiment is that the switching layer 114 is a multi-layer structure, and the conductive layer (the second electrode E2) is also a multi-layer structure. In FIG. 3, the second electrode E2 includes a first conductor layer 302 and a second conductor layer. A material of the first conductor layer 302 is, for example, titanium, tantalum, titanium nitride, tantalum nitride, aluminum titanium nitride, titanium tungsten, or a combination thereof. A material of the second conductor layer 304 is, for example, platinum, iridium, tungsten, ruthenium, graphite, or a combination thereof. A structure of the switching layer 114 includes a capping layer 306 and a switching layer 308. The capping layer 306 is generally an oxide with a lower resistivity, and the switching layer 308 is an oxide with a higher resistivity. An operating current and reliability of the element may be controlled through a reasonable collocation thereof. However, the disclosure is not limited thereto. The switching layer 114 may also be the multi-layer structure such as a three-layer structure or a four-layer structure.

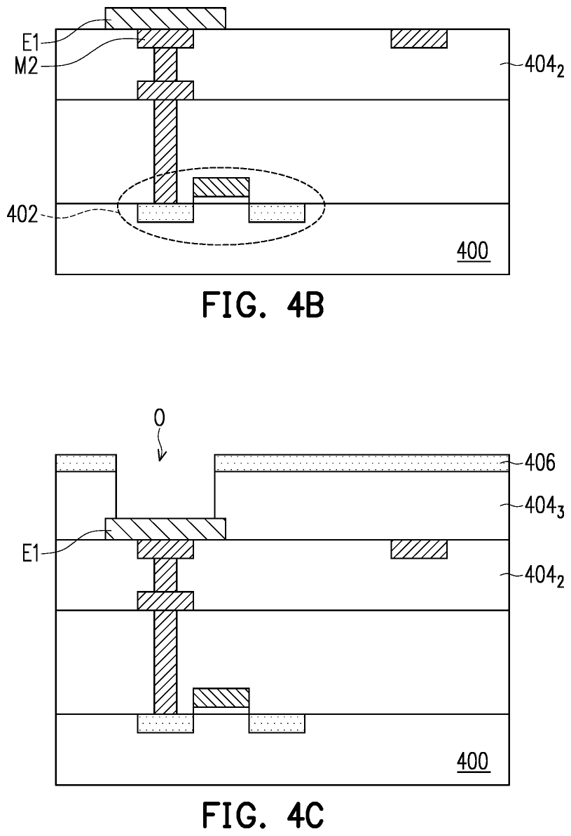

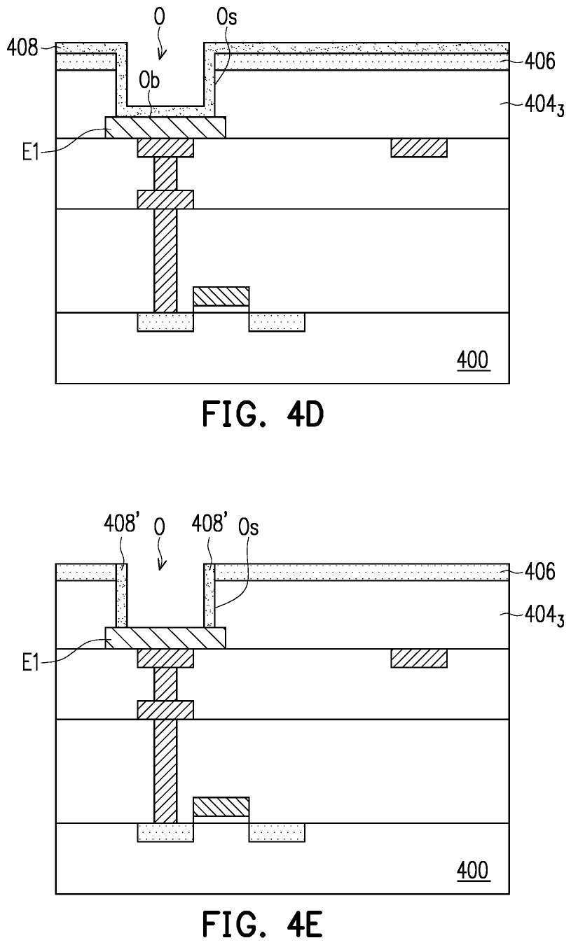

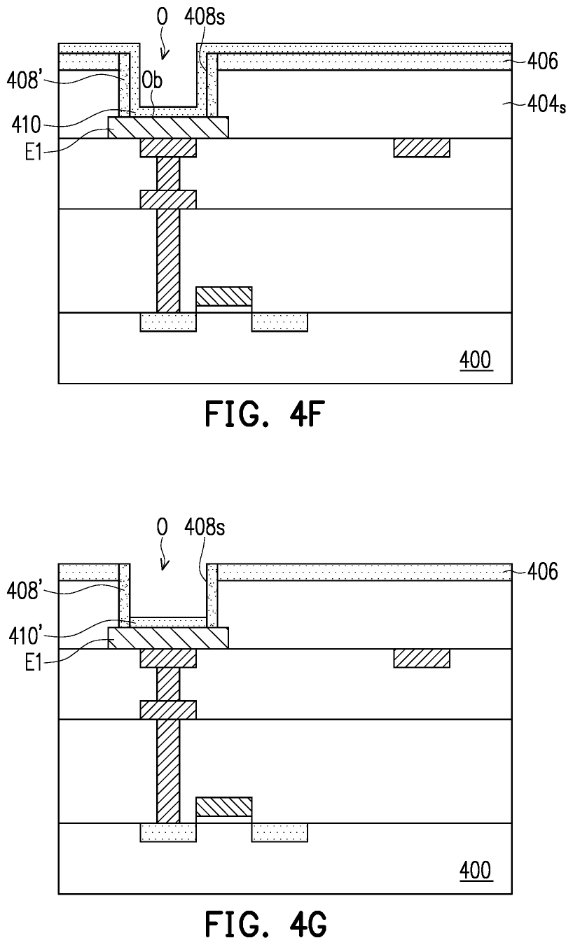

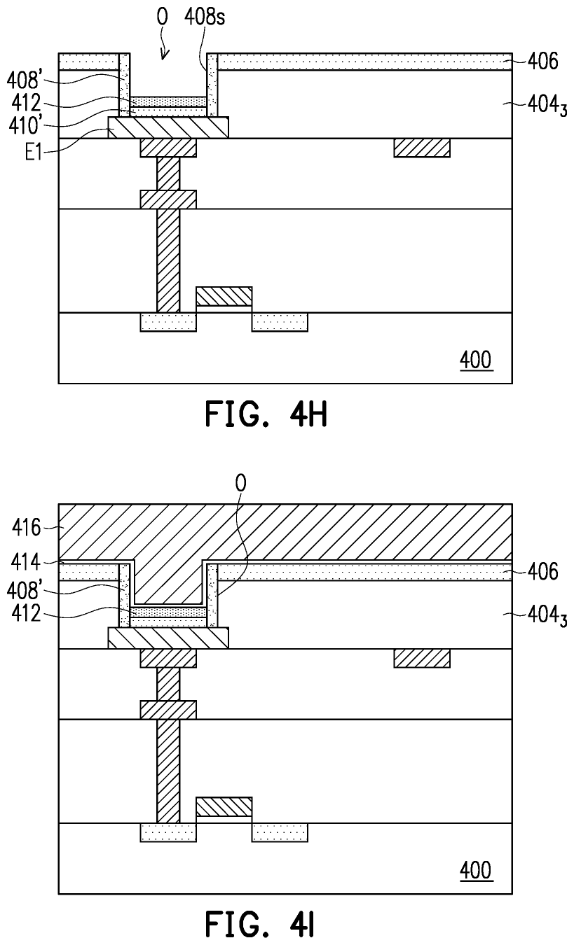

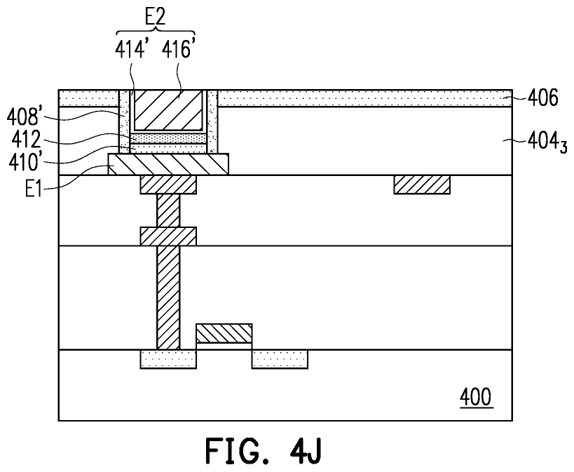

FIGS. 4A to 4J are schematic cross-sectional views of a manufacturing process of a resistive random access memory according to the fourth embodiment of the disclosure.

Referring to FIG. 4A, before the resistive random access memory is manufactured, a transistor 402 may be formed on a substrate 400 first, and then a dielectric layer 404₁, a contact C1, the interconnection metal layer M1, a dielectric layer 404₂, the via V1, and the interconnection metal layer M2 are sequentially formed. The manufacturing process of the above interconnection may be completed according to the conventional technology. Therefore, the same details will not be repeated in the following. In addition, the design of the interconnection, a structure of the transistor 402, etc. may be adjusted according to the requirements, and are not limited to those shown in FIG. 4.

Referring to FIG. 4B, the first electrode E1 is formed. For example, a conductive material is deposited on the dielectric layer 404₂ first, and then a pattern and a position of the first electrode E1 are defined by using photolithography and etching technology.

Then, referring to FIG. 4C, a dielectric layer 404₃ is first formed on the first electrode E1, and the opening O exposing the portion of the first electrode E1 is formed in the dielectric layer 404₃. A method of forming the opening O in the dielectric layer 404₃ is, for example, to first form a stop layer 406 on a surface of the dielectric layer 404₃, then form a hole in the stop layer 406 by using the photolithography and etching technology to expose a portion of the surface of the dielectric layer 404₃, and then use the stop layer 406 as an etching mask to etch the dielectric layer 404₃ until the first electrode E1 is exposed.

Afterwards, referring to FIG. 4D, in order to form the protection layer on a sidewall Os of the opening O, a protection material 408 may be first deposited on the dielectric layer 404₃ and the sidewall Os and a bottom Ob of the opening O.

Then, referring to FIG. 4E, the photolithography and etching technology or anisotropic etching is used for the protection material 408 in FIG. 4D until the first electrode E1 is exposed, and then a protection layer 408′ may be formed on the sidewall Os of the opening O. The protection layer 408′ may improve the performance and reliability of the resistive random access memory.

Next, referring to FIG. 4F, in order to form the switching layer of the multi-layer structure, a capping material 410 may be conformally deposited on a sidewall 408s of the protection layer 408′ and the bottom Ob of the opening O.

Then, referring to FIG. 4G, remove a portion of the capping material on the sidewall 408s of the protection layer 408′ is removed, and then a capping layer 410′ may be formed on the exposed portion of the first electrode E1 and expose a portion of the sidewall 408s of the protection layer 408′. Therefore, an area of the active region (where the capping layer 410′ is located) will not extend to an upper half of the opening O. Compared to a position of the capping material 410 in FIG. 4F, power consumption of the element will be smaller, and a filling window of a void in the subsequent manufacturing process will be larger. In an embodiment, a method of removing a portion of the capping material 410 in FIG. 4F is, for example, but not limited to the following. The opening O is filled with the material such as photoresist, and the recess process is performed on it to reserve a portion of the photoresist (not shown) in the opening O and expose the capping material 410 on the sidewall 408s, and then the remaining photoresist is used as the mask to etch and remove the exposed capping material 410 to obtain the capping layer 410′ in FIG. 4G. Since possible variations in the manufacturing process may affect a height of the photoresist used as the mask, the capping layer 410′ may be formed with an extension portion (the extension portion 114a shown in FIG. 2) on the sidewall 408s of the protection layer 408′.

Next, referring to FIG. 4H, a switching layer 412 may be formed on the capping layer 410′ according to the method shown in FIGS. 4F to 4G, and the rest may be derived by analog. In another embodiment, deposition of the capping material 410 and a switching material may also be completed first, and then the steps shown in FIG. 4G are performed to remove all the film layers on the sidewall 408s of the protection layer 408′, leaving a portion close to the first electrode E1 as the switching layer.

Then, referring to FIG. 4I, in order to form the conductive layer of the multi-layer structure, a first conductor material 414 may be deposited first, and then a second conductor material 416 may be deposited to fill the opening O. A material of the first conductor material 414 is, for example, titanium, tantalum, titanium nitride, tantalum nitride, aluminum titanium nitride, titanium tungsten, or a combination thereof. A material of the second conductor material 416 is, for example, platinum, iridium, tungsten, ruthenium, graphite, or a combination thereof.

After that, referring to FIG. 4J, a planarization process is performed to remove the conductive material other than the opening O (i.e., the first conductor material 414 and the second conductor material 416 in FIG. 4I) to obtain the second electrode E2 formed by a first conductor layer 414′ and a second conductor layer 416′. The planarization process may be a chemical mechanical polishing (CMP) process, and the stop layer 406 used in a process of forming the opening O may be used as a polishing stop layer.

Since the opening O is first formed in the method of the fourth embodiment, and then the layer structures of the resistive random access memory are deposited therein, there is no need for a long time and a high-power etching process to define the metal layer (such as the first electrode E1 and the second electrode E2), which may avoid plasma damage to the dielectric layer in the memory unit and prevent occurrence of arcing defects. In addition, a size of the opening O may be easily controlled in a required range. Therefore, an issue of a tilted outline of the memory unit caused by the long-time etching may be solved, thereby improving an area efficiency of the memory unit.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A resistive random access memory, comprising:
a first electrode;
a dielectric layer formed on the first electrode, wherein the dielectric layer has an opening exposing a portion of the first electrode;
a protection layer disposed on a sidewall of the opening;
at least one switching layer disposed on the exposed portion of the first electrode and exposing a portion of a sidewall of the protection layer; and
at least one conductive layer disposed on the at least one switching layer in the opening, wherein the at least one conductive layer is a second electrode.

2. The resistive random access memory according to claim 1, wherein the at least one switching layer comprises an extension portion extending on the sidewall of the protection layer.

3. The resistive random access memory according to claim 1, wherein the at least one switching layer is a single-layer structure or a multi-layer structure.

4. The resistive random access memory according to claim 1, wherein the at least one conductive layer is a single-layer structure or a multi-layer structure.

5. The resistive random access memory according to claim 1, further comprising a stop layer located on a surface of the dielectric layer.

6. The resistive random access memory according to claim 1, wherein the at least one conductive layer is in direct contact with the exposed portion of the sidewall of the protection layer.

7. A method of manufacturing a resistive random access memory, comprising:
forming a first electrode;
forming a dielectric layer on the first electrode;
forming an opening in the dielectric layer to expose a portion of the first electrode;
forming a protection layer on a sidewall of the opening;
forming at least one switching layer on the exposed portion of the first electrode and exposing a portion of a sidewall of the protection layer; and
forming at least one conductive layer on the at least one switching layer in the opening, wherein the at least one conductive layer is a second electrode.

8. The method of manufacturing the resistive random access memory according to claim 7, wherein forming the protection layer comprises:
depositing a protection material on the dielectric layer and the sidewall and a bottom of the opening; and
anisotropically etching the protection material until the first electrode is exposed.

9. The method of manufacturing the resistive random access memory according to claim 7, wherein forming the at least one switching layer comprises:
conformally depositing at least one switching material on the sidewall of the protection layer and a bottom of the opening; and
removing a portion of the at least one switching material on the sidewall of the protection layer.

10. The method of manufacturing the resistive random access memory according to claim 7, wherein forming the at least one conductive layer comprises:
depositing at least one conductive material to fill the opening; and
performing a planarization process to remove the at least one conductive material other than the opening.

11. The method of manufacturing the resistive random access memory according to claim 10, wherein the planarization process is a chemical mechanical polishing (CMP) process.

12. The method of manufacturing the resistive random access memory according to claim 7, wherein forming the opening in the dielectric layer comprises:
forming a stop layer on a surface of the dielectric layer, wherein the stop layer has a hole exposing a portion of the surface of the dielectric layer; and
etching the dielectric layer using the stop layer as an etching mask.

13. The method of manufacturing the resistive random access memory according to claim 12, wherein forming the at least one conductive layer comprises:
depositing at least one conductive material to fill the opening; and
using the stop layer as a polishing stop layer and performing a chemical mechanical polishing process to remove the at least one conductive material other than the opening.
